(19) United States
(12) Patent Application Publication
(10) Pub. No.: US 2024/0237332 A1
(43) Pub. Date: Jul. 11, 2024

(54) SEMICONDUCTOR DEVICE INCLUDING CAPACITOR

(71) Applicant: Samsung Electronics Co., Ltd., Suwon-si (KR)

(72) Inventors: Jungmin PARK, Suwon-si (KR); Hanjin LIM, Suwon-si (KR); Hyungsuk JUNG, Suwon-si (KR)

(73) Assignee: Samsung Electronics Co., Ltd., Suwon-si (KR)

(21) Appl. No.: 18/394,884

(22) Filed: Dec. 22, 2023

(30) Foreign Application Priority Data
Jan. 5, 2023 (KR) 10-2023-0001628

(51) Int. Cl. H10B 12/00

(52) U.S. Cl. CPC H10B 12/315; H01L 28/60; H10B 12/34

(57) ABSTRACT

A semiconductor device includes a structure including a conductive region, and a capacitor electrically connected to the conductive region of the structure. The capacitor includes a first electrode electrically connected to the conductive region, a second electrode on the first electrode, and a dielectric layer between the first electrode and the second electrode. At least one of the first electrode and the second electrode includes a first material layer including a first material region including a first crystalline region and a second crystalline region different from the first crystalline region, and a second material region between the first crystalline region and the second crystalline region, and a second material layer on the first material layer. At least a portion of the first material layer is between the second material layer and the dielectric layer. A material of the first material region is different from a material of the second material region.

### CROSS-REFERENCE TO RELATED APPLICATION(S)

This application claims the benefit under 35 USC 119(a) of Korean Patent Application No. 10-2023-0001628 filed on Jan. 5, 2023 in the Korean Intellectual Property Office, the entire disclosure of which is incorporated herein by reference for all purposes.

### BACKGROUND

Various example embodiments relate to a semiconductor device including a capacitor and/or a method of manufacturing the same.

Research is being conducted to reduce the size of elements included in semiconductor devices and to improve performance thereof. For example, in a memory device such as a DRAM, research is being conducted to more reliably and/or more stably form reduced-size elements.

### SUMMARY

Various example embodiments provide a semiconductor device including a capacitor having improved performance.

Alternatively or additionally, various example embodiments provide a method of manufacturing the semiconductor device.

A semiconductor device according to various example embodiments is provided. The semiconductor device includes a structure including a conductive region, and a capacitor electrically connected to the conductive region of the structure. The capacitor includes a first electrode electrically connected to the conductive region, a second electrode on the first electrode, and a dielectric layer between the first electrode and the second electrode. At least one of the first electrode and the second electrode includes a first material layer including a first material region including a first crystalline region and a second crystalline region different from the first crystalline region, and a second material region between the first crystalline region and the second crystalline region, and a second material layer on the first material layer. At least a portion of the first material layer is between the second material layer and the dielectric layer, and a material of the first material region is different from a material of the second material region.

Alternatively or additionally a semiconductor device according to some example embodiments is provided. The semiconductor device includes a structure including conductive regions, and a capacitor electrically connected to the structure. The capacitor includes first electrodes electrically connected to the conductive regions, a second electrode on the first electrodes, and a dielectric layer between the first electrodes and the second electrode. At least one of the first electrodes and the second electrode includes a first material region including a first crystalline region having a (111) crystal plane and a second crystalline region having a (200) crystal plane, and a second material region between the first crystalline region and the second crystalline region. A material of the first material region is different from a material of the second material region, and in the first material region, a volume of the second crystalline region is greater than or equal to a volume of the first crystalline region.

Alternatively or additionally, a semiconductor device according to various example embodiments is provided. The semiconductor device includes a structure including conductive regions, and a memory element electrically connected to the conductive regions of the structure. The memory element includes first electrodes electrically connected to the conductive regions, a second electrode on the first electrodes, and a dielectric layer between the first electrodes and the second electrode. At least one of the first electrodes and the second electrode includes a first material region including a first crystalline region of a first columnar shape and a second crystalline region of a second columnar shape, different from the first columnar shape, and a second material region between the first crystalline region and the second crystalline region. A material of the first material region is different form a material of the second material region. In the first material region, a volume of the second crystalline region is equal to or greater than a volume of the first crystalline region, and a work function of the second crystalline region is greater than a work function of the first crystalline region.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a cross-sectional view conceptually illustrating a semiconductor device according to some example embodiments;

FIG. 2 is a cross-sectional view conceptually illustrating a modified example of a semiconductor device according to some example embodiments;

FIG. 3 is a cross-sectional view conceptually illustrating a modified example of a semiconductor device according to some example embodiments;

FIG. 4 is a cross-sectional view conceptually illustrating a modified example of a semiconductor device according to some example embodiments;

FIG. 5 is a cross-sectional view conceptually illustrating a modified example of a semiconductor device according to some example embodiments;

FIG. 6 is a partially enlarged cross-sectional view conceptually illustrating a modified example of a semiconductor device according to some example embodiments;

FIG. 7 is a conceptual diagram conceptually illustrating an illustrative example of a semiconductor device according to some example embodiments;

FIGS. 8 and 9 are diagrams conceptually illustrating a modified example of a semiconductor device according to some example embodiments;

FIGS. 10 and 11 are diagrams conceptually illustrating modified examples of a semiconductor device according to some example embodiments;

FIG. 12 is a cross-sectional view conceptually illustrating a modified example of a semiconductor device according to some example embodiments; and

FIGS. 13 to 17 are diagrams conceptually illustrating an illustrative example of a method of forming a semiconductor device according to some example embodiments.

### DETAILED DESCRIPTION

Hereinafter, terms such as “upper,” “middle,” “lower,” and the like may be replaced with other terms, such as “first,” “second,” “third,” and the like, and used to describe the elements of the specification. Terms such as “first,” “second,” “third” and the like may be used to describe various elements, but the elements are not limited by the terms, and a “first element” may be referred to as a “second element”.

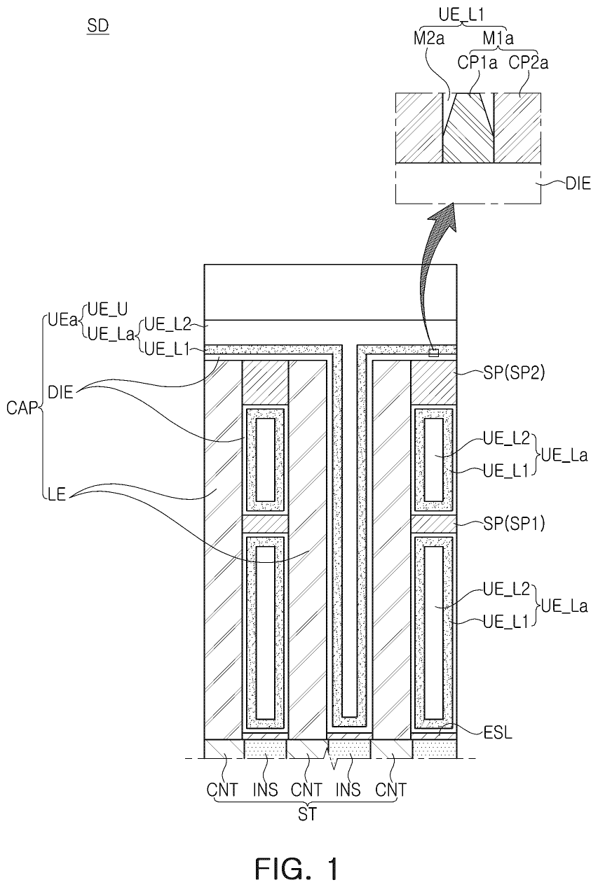

Referring to FIG. 1, an illustrative example of a semiconductor device according to some example embodiments will be described. FIG. 1 is a cross-sectional view conceptually illustrating a semiconductor device according to some example embodiments.

Referring to FIG. 1, a semiconductor device SD according to some example embodiments may include a structure ST including a conductive region CNT, and a capacitor (CAP) electrically connected to the conductive region CNT of the structure ST.

In the structure ST, the conductive region CNT may be or may include or be included in a contact structure electrically connected to a source/drain region of a cell transistor. The conductive region CNT may also be referred to by terms such as one or more of a contact structure, a contact plug, or a pad pattern. The conductive region CNT may include a conductive material. For example, the conductive region CNT may include at least one of doped silicon such as p-doped or n-doped single-crystal or polycrystal silicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, and/or carbon nanotubes.

The structure ST may further include an insulating pattern INS. The insulating pattern INS may cover at least a portion of a side surface of the conductive region CNT. An upper surface of the insulating pattern INS may be coplanar with an upper surface of the conductive region CNT. The insulating pattern INS may include an insulating material such as silicon oxide or silicon nitride.

The semiconductor device SD may further include an etch stop layer ESL on the insulating pattern INS. The etch stop layer ESL may be formed of or include an insulating material. For example, the etch stop layer ESL may include at least one of a SiBN material and a SiCN material.

The capacitor CAP may include a first electrode LE connected to the conductive region CNT of the structure ST, a top cell plate or a second electrode UEa on the first electrode LE, and a dielectric layer DIE between the first electrode LE and the second electrode UEa.

The capacitor CAP may be or may include or correspond to a capacitor of a memory cell storing information in a DRAM device. The capacitor CAP may also be referred to as an information storage structure or a memory element. In some example embodiments, the capacitor CAP may have memristor properties; however, example embodiments are not limited thereto.

In some example embodiments, a plurality of conductive regions CNT may be disposed or arranged, and a plurality of first electrodes LE spaced apart from each other may be disposed or arranged. In this case, one first electrode LE among the plurality of first electrodes LE will be mainly described.

The first electrode LE may contact and be electrically connected to the conductive region CNT, pass through the etch stop layer ESL, and extend upwardly. The first electrode LE may have a columnar or prismatic shape, but example embodiments are not limited thereto. For example, the first electrode LE may have a cylindrical shape. The first electrode LE may include a doped semiconductor such as doped polysilicon, a metal, a conductive metal nitride, a metal-semiconductor compound, a conductive metal oxide, or combinations thereof.

The dielectric layer DIE may include a high-k dielectric, silicon oxide, silicon nitride, silicon oxynitride, or combinations thereof. In this case, the high-k dielectric may be a dielectric having a dielectric constant greater than that of silicon oxide. For example, the high-k dielectric may be a metal oxide. For example, the high-k dielectric may include at least one of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide and aluminum oxide.

The second electrode UEa may include a first material layer UE_L1 and a second material layer UE_L2 on the first material layer UE_L1. The first material layer UE_L1 may be disposed between the dielectric layer DIE and the second material layer UE_L2. The second material layer UE_L2 may be spaced apart from the dielectric layer DIE by the first material layer UE_L1.

The first material layer UE_L1 may include a first material region M1a including a first crystalline region CP1a and a second crystalline region CP2a different from the first crystalline region CP1a, and a second material region M2a between (e.g., horizontally between) the first crystalline region CP1a and the second crystalline region CP2a. At least a portion of the first material layer UE_L1 may be disposed between the second material layer UE_L2 and the dielectric layer DIE. A material of the first material region M1a may be different from a material of the second material region M2a. For example, there may not be a common material between the first material region M1a and the second material region M2a.

The first material region M1a may contact (or directly contact) the dielectric layer DIE.

The second material region M2a may be spaced apart from (or may not directly contact) the dielectric layer DIE.

A material of the first material region M1a may be a metal nitride. For example, the material of the first material region M1a may include at least one of TiN, CrN, NbN, HfN, and/or ZrN. In some example embodiments, the first material region M1a may consist of or consist essentially of at least one of TiN, CrN, NbN, HfN, and/or ZrN.

The material of the second material region M2a may include at least one of Al, Si, and/or B. In some example embodiments, the second material region M2a may consist of or consist essentially of at least one of Al, Si, and/or B.

In some example embodiments, any materials included in the first material region M1a may not be included in any materials included in the second material region M2a. For example, there may not be a common overlapping material between the first material region M1a and the second material region M2a.

To reduce or to significantly reduce the leakage current of the capacitor CAP and increase the capacitance of the capacitor, the second material region M2a in the first material layer UE_L1 may have about 20 at % or less. For example, an atomic concentration of the materials included in the second material region M2a with respect to the first material layer UE_L1 may be about 20 at % or less.

To reduce or significantly reduce the leakage current of the capacitor CAP and increase the capacitance of the capacitor, the thickness of the first material layer UE_L1 may be in a range of about 10 Å to about 40 Å.

The first crystalline region CP1a may have a (111) crystal plane, e.g., may have a single-crystal or at least one grain of crystal of one or more of TiN, CrN, NbN, HfN, and/or ZrN arranged in a (111) plane, and the second crystalline region CP2a may have a (200) crystal plane, e.g., may have a single-crystal or at least one grain of crystal of one or more of TiN, CrN, NbN, HfN, and/or ZrN arranged in a (200) plane. For example, the first material region M1a may be formed of TiN, the first crystalline region CP1a may have a (111) crystal plane, and the second crystalline region CP2a may have a (200) crystal plane. In this case, to reduce or significantly reduce the leakage current of the capacitor CAP and increase the capacitance of the capacitor, among the first crystalline region CP1a and the second crystalline region CP2a in the first material layer UE_L1, the second crystalline region CP2a may account for about 50% or more by volume. In some example embodiments, an orientation of the first crystalline region CP1a and/or the second crystalline region CP2a may be determined by one or more of various analytical methods, such as but not limited to transmission electron microscopy (TEM) and/or x-ray diffraction (XRD); however, example embodiments are not limited thereto.

The second material layer UE_L2 may include the same material as that of the first material region M1a. For example, the material of the first material region M1a and a material of the second material layer UE_L2 may include at least one of TiN, CrN, NbN, HfN, or ZrN.

The first crystalline region CP1a may have a first work function, and the second crystalline region CP2a may have a second work function. In this case, the second work function may be greater than the first work function. For example, the first crystalline region CP1a may have a work function of about 4.4 eV, and the second crystalline region CP2a may have a work function of about 4.6 eV.

In the first material region M1a, an amount of the second crystalline region CP2a in the first crystalline region CP1a and the second crystalline region CP2a may be about 50% or more, and in the second material layer UE_L2, the amount of the crystalline region having the (111) crystal plane may be greater than the amount of the crystalline region having the (200) crystal plane. Therefore, since the amount of the second crystalline region CP2a having a greater work function than the first crystalline region CP1a is equal to or greater than that of the first crystalline region CP1a, the leakage current characteristic of the capacitor CAP may be improved.

The second electrode UEa may further include a third material layer UE_U on the second material layer UE_L2. The third material layer UE_U may include a material different from materials of the first and second material layers UE_L1 and UE_L2. For example, the third material layer UE_U may include a material such as SiGe and/or W.

The first and second material layers UE_L1 and UE_L2 may be referred to as a first upper electrode layer UE_La, and the third material layer UE_U may be referred to as a second upper electrode layer.

The first electrode LE may not include the same material layer as the first material layer UE_L1 of the second electrode UEa. In some example embodiments, the first electrode LE and the second electrode UEa may not include any common material.

The semiconductor device SD may include at least one support layer SP contacting a side surface of the first electrode LE. For example, when the first electrode LE is plural, and to prevent or reduce the likelihood of a collapse and/or a deformation of the plurality of first electrodes LE, the at least one support layer SP may be disposed between the plurality of first electrodes LE and may have an opening.

The at least one support layer SP may include a lower support layer SP1 and an upper support layer SP2 disposed on different levels. The upper support layer SP2 may contact an upper region of the first electrode LE, and the lower support layer SP1 may contact the first electrode LE at a level lower than that of the upper support layer SP2. The at least one support layer SP may include an insulating material such as silicon nitride.

In the capacitor CAP, the dielectric layer DIE may be disposed along surfaces of the first electrode LE and the at least one support layer SP contacting the first electrode LE, and the second electrode UEa may cover the dielectric layer DIE. Among the first and second material layers UE_L1 and UE_L2 of the first upper electrode layer UE_La, the second material layer UE_L2 may continuously extend from an area positioned at a level higher than the upper end of the first electrode LE to an area positioned at a level lower than the upper end of the first electrode LE. Therefore, when the number of first electrodes LE is plural, the second material layer UE_L2 is disposed between the first electrodes LE adjacent to each other and extends upwardly, and may be disposed at a level higher than upper ends of the first electrodes LE. The third material layer, for example, the second upper electrode layer UE_U may contact the second material layer UE_L2 and may be spaced apart from the first material layer UE_L1.

Hereinafter, various modified examples of the elements of the above-described example embodiments will be described. Various modified examples of the elements of the above-described example embodiments described below will be described focusing on the modified or replaced elements. In addition, elements that may be modified or replaced described below are described with reference to the following drawings, but the elements that may be modified or replaced are combined with each other or with the elements described above to configure a semiconductor device according to the example embodiment.

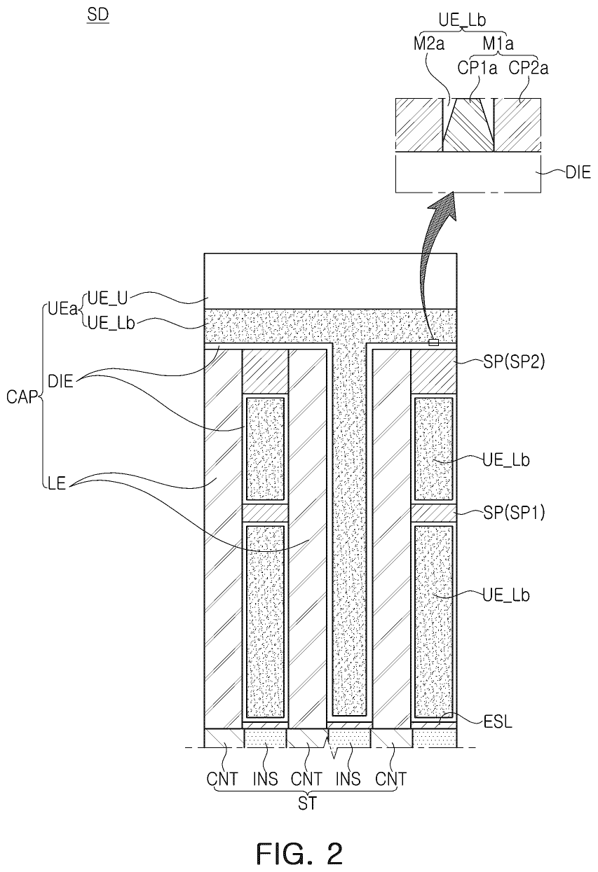

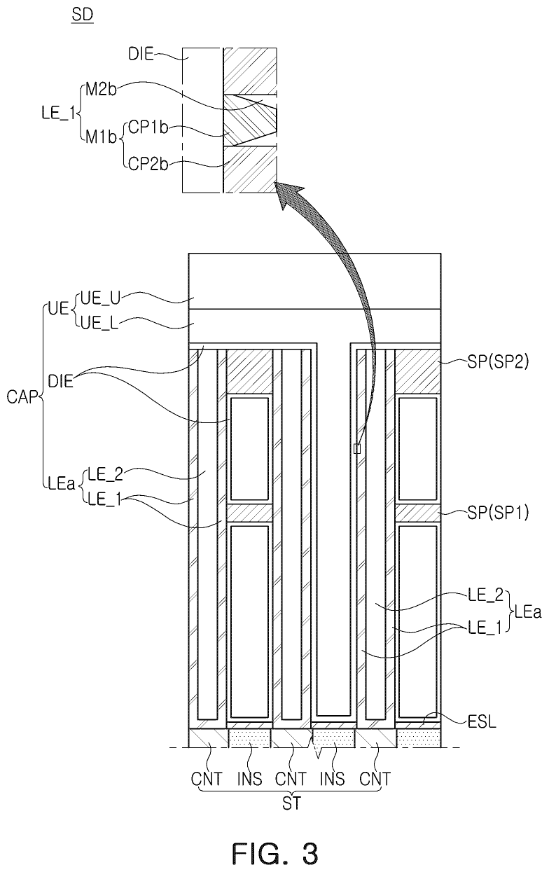

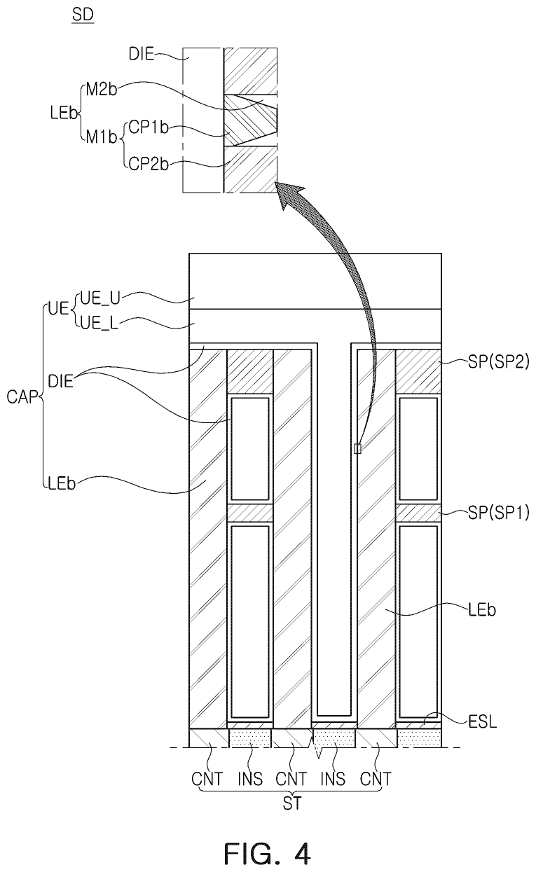

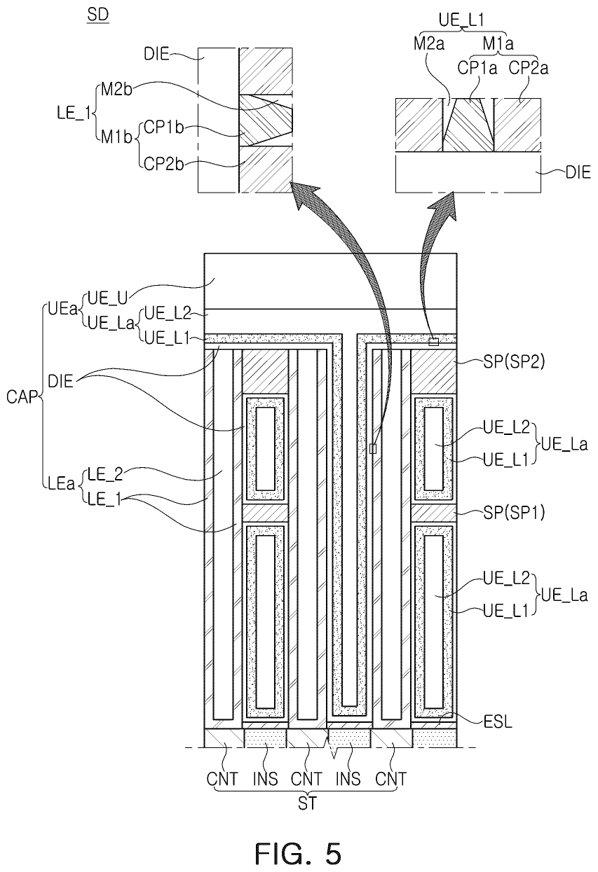

Various modified examples of at least one of the first and second electrodes LE and UEa of the capacitor CAP will be described with reference to FIGS. 2 to 5, respectively. FIG. 2 is a cross-sectional view illustrating some modified examples of the second electrode (UEa in FIG. 1) described in FIG. 1, FIG. 3 is a cross-sectional view illustrating some modified examples of the first electrode (LE in FIG. 1) described in FIG. 1, FIG. 4 is a cross-sectional view illustrating some modified examples of the first electrode (LE in FIG. 1) described in FIG. 1, and FIG. 5 is a cross-sectional view illustrating modified examples of the first electrode (LE in FIG. 1) and the second electrode (UEa in FIG. 1) described in FIG. 1.

In a modified example, referring to FIG. 2, among the first and second material layers (UE_L1 and UE_L2 in FIG. 1) of the first upper electrode layer (UE_La in FIG. 1) described in FIG. 1, the second material layer (UE_L2 in FIG. 1) may be replaced with a material of the first material layer (UE_L1 in FIG. 1). Therefore, the first upper electrode layer (UE_La in FIG. 1) described in FIG. 1 may be transformed into the first upper electrode layer UE_Lb that may be formed of the material of the first material layer (UE_L1 in FIG. 1) described with reference to FIG. 1. Accordingly, the first upper electrode layer UE_Lb may include the first material region M1a including the first crystalline region CP1a and the second crystalline region CP2a as described in FIG. 1, and the second material region M2a.

In some modified examples, referring to FIG. 3, the first electrode (LE in FIG. 1) described in FIG. 1 may be replaced with a first electrode LEa including a first material layer LE_1 and a second material layer LE_2. The first material layer LE_1 may be disposed between the dielectric layer DIE and the second material layer LE_2.

When the first electrode LEa has a columnar shape, the second material layer LE_2 of the first electrode LEa has a columnar shape, and the first material layer LE_1 of the first electrode LEa may have a U shape covering the side and lower surfaces of the second material layer LE_2. Upper ends of the first and second material layers LE_1 and LE_2 of the first electrode LEa may contact the dielectric layer DIE.

The first material layer LE_1 may include a first material region M1b including a first crystalline region CP1b and a second crystalline region CP2b different from the first crystalline region CP1b, and a second material region M2b between the first crystalline region CP1b and the second crystalline region CP2b.

The first material layer LE_1 of the first electrode LEa may be formed of or may include substantially the same material as the first material layer (UE_L1 of FIG. 1) of the second electrode UEa described with reference to FIG. 1. The second material layer LE_2 of the first electrode LEa may be formed of or may include substantially the same material as the second material layer (UE_L2 of FIG. 1) of the second electrode UEa described with reference to FIG. 1.

A material of the first material region M1b may be a metal nitride; for example, the first material region M1b may consist of or consist essentially of a metal nitride. For example, the material of the first material region M1b may include at least one of TiN, CrN, NbN, HfN, and/or ZrN.

a material of the second material region M2b may include at least one of Al, Si, and/or B, and may or may not include any other materials.

To reduce or to significantly reduce the leakage current of the capacitor CAP and increase the capacitance of the capacitor, the second material region M2b may be formed to have about 20 at % or less of the material in the first material layer LE_1 of the first electrode LEa.

To reduce or to significantly reduce the leakage current of the capacitor CAP and increase the capacitance of the capacitor, the thickness of the first material layer LE_1 of the first electrode LEa may be in the range of about 10 Å to about 40 Å.

The first crystalline region CP1b may have a single crystal and/or a grain in a (111) crystal plane, and the second crystalline region CP2b may have a single crystal and/or a grain in a (200) crystal plane. For example, the first material region M1b may be formed of TiN, the first crystalline region CP1b may be arranged to have a (111) crystal plane, and the second crystalline region CP2b may be arranged to have a (200) crystal plane. In this case, to reduce or significantly reduce the leakage current of the capacitor CAP and increase the capacitance of the capacitor, among the first crystalline region CP1b and the second crystalline region CP2b in the first material layer LE_1 of the first electrode LEa, the second crystalline region CP2b may account for about 50% or more by volume.

In the first electrode LEa, the second material layer LE_2 may include the same material as that of the first material region M1b. In the first material region M1b, an amount of the second crystalline region CP2b of the first crystalline region CP1b and the second crystalline region CP2b may be about 50% or more, and in the second material layer LE_2, the amount of crystalline regions having (111) crystal planes may be greater than the amount of crystalline regions having (200) crystal planes.

In the second electrode (UEa in FIG. 1) described in FIG. 1, the first upper electrode layer UE_La may be transformed into a first upper electrode layer UE_L that does not include the first material layer (UE_L1 in FIG. 1). The first upper electrode layer UE_L may include a doped semiconductor such as doped single-crystal or polycrystalline silicon, a metal, a conductive metal nitride, a metal-semiconductor compound, a conductive metal oxide, or combinations thereof. Therefore, the second electrode (UEa in FIG. 1) described in FIG. 1 may be transformed into a second electrode UE including the first upper electrode layer UE_L and the second upper electrode layer UE_U described in FIG. 1.

In some modified examples, referring to FIG. 4, among the first and second material layers (LE_1 and LE_2 of FIG. 3) of the first electrode (LEa of FIG. 3) described in FIG. 3, the second material layer (LE_2 of FIG. 3) may be replaced with the material of the first material layer (LE_1 of FIG. 3). Therefore, the first electrode (LEa in FIG. 3) described in FIG. 3 may be transformed into a first electrode (LEb) that may be formed of the material of the first material layer (LE_1 in FIG. 3) described in FIG. 3. Accordingly, the first electrode LEb may include the first material region M1b including the first crystalline region CP1b and the second crystalline region CP2b as described in FIG. 3, and the second material region M2b.

In some modified examples, referring to FIG. 5, in a capacitor CAP including a first electrode, a dielectric layer DIE, and a second electrode, the first electrode may be either the first electrode described in FIG. 3 (LEa in FIG. 3) or the first electrode described in FIG. 4 (LEb in FIG. 4), and the second electrode may be the second electrode (UEa in FIG. 1) described in FIG. 1 or the second electrode (UEa in FIG. 2) described in FIG. 2. For example, as illustrated in FIG. 5, the capacitor CAP may include the first electrode (LEa in FIG. 3) described in FIG. 3, the second electrode (UEa in FIG. 1) described in FIG. 1, and the dielectric layer DIE between the first electrode LEa and the second electrode UEa.

As described in FIG. 3, the first material layer LE_1 of the first electrode LEa may include a first material region M1b including the first crystalline region CP1b and the second crystalline region CP2b, and a second material region M2b between the first crystalline region CP1b and the second crystalline region CP2b. As described in FIG. 1, the first material layer UE_L1 of the second electrode UEa may include a first material region M1a including the first crystalline region CP1a and the second crystalline region CP2a, and a second material region M2a between the first crystalline region CP1a and the second crystalline region CP2a.

The first material layer LE_1 of the first electrode LEa and the first material layer UE_L1 of the second electrode UEa may significantly reduce leakage current of the capacitor CAP and increase capacitance of the capacitor.

To distinguish the first material layer LE_1 of the first electrode LEa from the first material layer (UE_L1 in FIG. 1) of the second electrode UEa, the first material layer LE_1 of the first electrode LEa may be referred to as a first lower material layer, and the first material layer (UE_L1 in FIG. 1) of the second electrode UEa described with reference to FIG. 1 may be referred to as a first upper material layer. In addition, the second material layer LE_2 of the first electrode LEa is referred to as a second lower material layer, and the second material layer (UE_L2 in FIG. 1) of the second electrode UEa described in FIG. 1 may be referred to as a second upper material layer.

To improve or help to improve the productivity of the semiconductor device SD, one of the first material layer LE_1 of the first electrode LEa and the first material layer UE_L1 of the second electrode UEa is omitted, and thus, a semiconductor device SD including any one of the capacitors CAP described in FIGS. 1 to 4 may be provided.

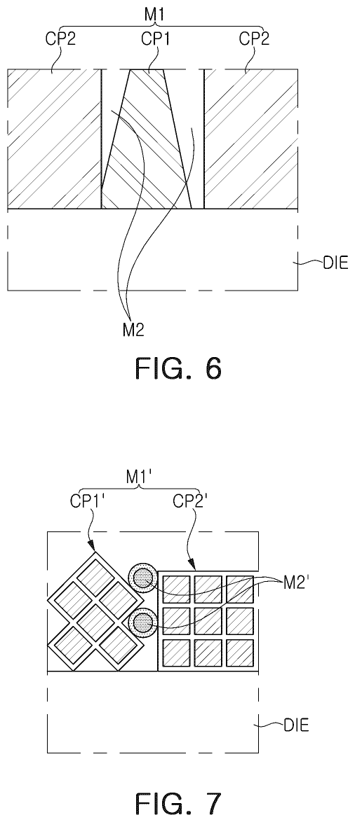

Next, with reference to FIG. 6, modified examples of the first material regions M1a and M1b and the second material regions M2a and M2b in FIGS. 1 to 5 will be described. FIG. 6 is a partially enlarged cross-sectional view illustrating a modified example of the first material regions M1a and M1b and the second material regions M2a and M2b in FIGS. 1 to 5.

In some modified examples, referring to FIG. 6, in at least one of the first electrode of FIG. 3 (LEa of FIG. 3), the first electrode of FIG. 4 (LEb of FIG. 4) and the first electrode of FIG. 5 (LEa of FIG. 5), the second material region M2b spaced apart from the dielectric layer DIE may be transformed into a second material region M2 contacting the dielectric layer DIE. Therefore, at least one of the first electrode in FIG. 3 (LEa in FIG. 3), the first electrode in FIG. 4 (LEb in FIG. 4), and the first electrode in FIG. 5 (LEa in FIG. 5) may include a first material region M1 including a first crystalline region CP1 and a second crystalline region CP2, and a second material region M2 disposed between the first crystalline region CP1 and the second crystalline region CP2. In this case, the first crystalline region CP1 may be substantially the same as the first crystalline region CP1b in FIG. 3, and the second crystalline region CP2 may be substantially the same as the second crystalline region CP2b in FIG. 3. Accordingly, the material(s) of the first material region M1 may be the same as that of the first material region M1b in FIG. 3. The material(s) of the second material region M2 may be the same as that of the second material region M2b in FIG. 3.

In at least one of the second electrode of FIG. 1 (UEa of FIG. 1), the second electrode of FIG. 2 (UEa of FIG. 2) and the second electrode of FIG. 5 (UEa of FIG. 5), the second material region M2a spaced apart from the dielectric layer DIE may be transformed into a second material region M2 contacting the dielectric layer DIE. Therefore, at least one of the second electrode of FIG. 1 (UEa of FIG. 1), the second electrode of FIG. 2 (UEa of FIG. 2) and the second electrode of FIG. 5 (UEa of FIG. 5) may include a first material region M1 including a first crystalline region CP1 and a second crystalline region CP2, and a second material region M2 disposed between the first crystalline region CP1 and the second crystalline region CP2. In this case, the first crystalline region CP1 may be substantially the same as the first crystalline region CP1a in FIG. 1, and the second crystalline region CP2 may be substantially the same as the second crystalline region CP2a in FIG. 1. Accordingly, the material(s) of the first material region M1 may be the same as that of the first material region M1a in FIG. 1, and the material(s) of the second material region M2 may be the same as that of the second material region M2a in FIG. 1.

Next, illustrative examples of the first material regions M1a, M1b, and M1 and the second material regions M2a, M2b, and M2 described with reference to FIGS. 1 to 6 will be described with reference to FIG. 7. FIG. 7 is a schematic diagram illustrating an illustrative example of the first material regions M1a, M1b, and M1 and the second material regions M2a, M2b, and M2 described in FIGS. 1 to 6.

Referring to FIG. 7, the first material regions M1a, M1b, and M1 described in FIGS. 1 to 6 may include a first crystalline region CP1′ having a first columnar shape grown with a first grain orientation and having a first grain orientation, and a second crystalline region CP2′ having a second columnar shape having a second grain orientation by growing with a second grain orientation different from the first grain orientation. For example, the first crystalline region CP1′ may be formed by grain growth in a (111) direction, and the second crystalline region CP2′ may be formed by grain growth in a (200) direction.

The second material regions M2a, M2b, and M2 described with reference to FIGS. 1 to 6 are inserted and/or doped between the first crystalline region CP1′ of the first columnar shape and the second crystalline region CP2′ of the second columnar shape, and may serve to suppress or at least partially suppress the preferential growth of the first crystalline region CP1′ in the (111) direction and to allow or to help allow the second crystalline region CP2′ to be formed more favorably than the first crystalline region CP1′.

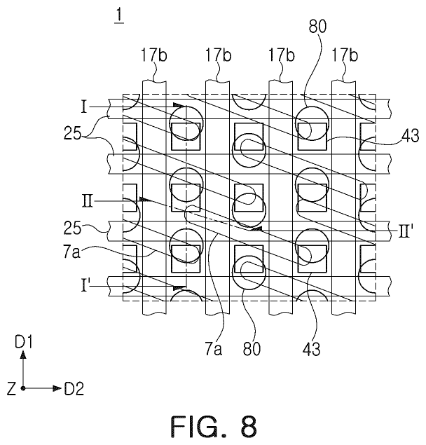

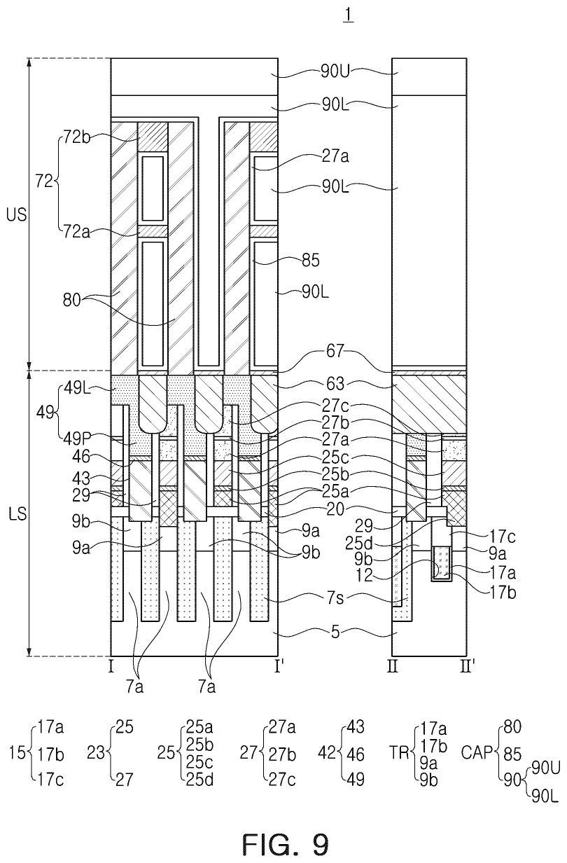

Next, with reference to FIGS. 8 and 9, an illustrative example of a semiconductor device according to some example embodiments will be described. FIGS. 8 and 9 are diagrams conceptually illustrating a modified example of a semiconductor device according to some example embodiments. FIG. 8 is a top view conceptually illustrating an illustrative example of a semiconductor device according to some example embodiments, and FIG. 9 is a cross-sectional view conceptually illustrating regions taken along lines I-I′ and II-II′ of FIG. 8.

Referring to FIGS. 8 and 9, a semiconductor device 1 according to some example embodiments may include a lower structure LS and an upper structure US on the lower structure LS.

The lower structure LS may include a substrate 5, active regions 7a disposed on the substrate 5, and device isolation regions 7s defining the active regions 7a.

The substrate 5 may be or may include a semiconductor substrate. For example, the substrate 5 may include a Group IV semiconductor, a Group III-V compound semiconductor, or a Group II-VI compound semiconductor. For example, the group IV semiconductor may include one or more of silicon, germanium, or silicon-germanium. For example, the substrate 5 may include a silicon material, for example, a single crystal silicon material. The substrate 5 may be or may include a silicon substrate, a silicon on insulator (SOI) substrate, a germanium substrate, a germanium on insulator (GOI) substrate, a silicon-germanium substrate, or a substrate including an epitaxial layer.

The device isolation region 7s may be a trench device isolation layer, e.g. a shallow trench isolation (STI) layer. The device isolation region 7s may be disposed on the substrate 5 and may define side surfaces of the active regions 7a. The device isolation region 7s may include an insulating material such as silicon oxide and/or silicon nitride. The active regions 7a may protrude from the substrate 5 in the vertical direction Z.

The lower structure LS may include gate trenches 12 crossing the active regions 7a and extending to the device isolation region 7s, gate structures 15 disposed in the gate trenches 12, and first impurity regions 9a and second impurity regions 9b disposed in the active regions 7a adjacent to side surfaces of the gate structures 15.

Each of the gate structures 15 may have a line shape extending in the first direction D1. Each of the active regions 7a may have a bar shape extending in an oblique direction with respect to the first direction D1. One cell active region of the active regions 7a may cross a pair of adjacent cell gate structures among the gate structures 15.

In one active region 7a of the active regions 7a, one pair of second impurity regions 9b and one first impurity region 9a between the pair of impurity regions 9b may be disposed. In one of the active regions 7a, the first and second impurity regions 9a and 9b may be spaced apart from each other by a pair of cell gate structures 15. In some example embodiments, a conductivity type of the first and second impurity regions may be the same as each other, e.g. may both be N-type conductivity regions or may both be P-type conductivity regions; however, example embodiments are not limited thereto.

In some example embodiments, the first impurity region 9a may be referred to as a first source/drain region, and the second impurity region 9b may be referred to as a second source/drain region.

Each of the gate structures 15 may include agate dielectric layer 17a conformally covering the inner wall of the gate trench 12, a gate electrode 17b disposed on the gate dielectric layer 17a and partially filling the gate trench 12, and a gate capping layer 17c disposed on the gate electrode 17b and filling the remaining portion of the gate trench 12.

The gate dielectric layer 17a, the gate electrode 17b, the first impurity region 9a and the second impurity region 9b may constitute or be included in a cell transistor.

The gate dielectric layer 17a may include at least one of silicon oxide and a high-k dielectric. The high-k dielectric may include a metal oxide and/or a metal oxynitride. The gate electrode 17b may be a row line or a word line of a memory semiconductor device such as DRAM. The gate electrode 17b may include doped polysilicon, metal, conductive metal nitride, metal-semiconductor compound, conductive metal oxide, graphene, carbon nanotube, or combinations thereof. The gate capping layer 17c may include an insulating material, for example, silicon nitride.

The lower structure LS may further include a buffer insulating layer 20 disposed on the active regions 7a, the device isolation region 7s, and the gate structures 15.

The lower structure LS may further include bit line structures 23 and contact structures 42. Each of the bit line structures 23 may include a column line or a bit line 25 and a bit line capping pattern 27 sequentially stacked. The bit line 25 may have a line shape extending in a second direction D2 perpendicular to the first direction D1. The bit line 25 may be formed of a conductive material. The bit line 25 may include a first bit line layer 25a, a second bit line layer 25b, and a third bit line layer 25c sequentially stacked. For example, the first bit line layer 25a may include doped silicon, for example, polysilicon having an N-type conductivity, and the second and third bit line layers 25b and 25c may include different conductive materials among, for example, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, and/or carbon nanotubes.

The bit line capping pattern 27 may include a first bit line capping layer 27a, a second bit line capping layer 27b, and a third bit line capping layer 27c sequentially stacked. The bit line capping pattern 27 may be formed of or may include an insulating material. Each of the first to third bit line capping layers 27a, 27b, and 27c may be formed of or include silicon nitride or a silicon nitride-based insulating material.

Each of the bit lines 25 may further include a bit line contact portion 25d extending downward from the first bit line layer 25a and electrically connected to the first impurity region 9a. The bit line 25 may be formed on the buffer insulating layer 20, and the bit line contact portion 25d of the bit line 25 penetrates the buffer insulating layer 20 and may contact the first impurity region 9a.

Each of the contact structures 42 may include a lower contact plug 43 penetrating the buffer insulating layer 20 and contacting the second impurity region 9b, an upper contact plug 49 on the lower contact plug 43, and a metal-semiconductor compound layer 46 between the lower contact plug 43 and the upper contact plug 49. The lower contact plug 43 may include doped silicon, for example, polysilicon having an N-type conductivity. The upper contact plug 49 may include a plug portion 49P, and a pad portion 49L disposed on the plug portion 49P and vertically overlapping a portion of the adjacent bit line capping pattern 27.

The lower structure LS may further include a bit line spacer 29 that contacts side surfaces of the bit line structure 23 and may be formed of an insulating material.

The lower structure LS may further include an insulating pattern 63 that penetrates between the pad portions 49L of the contact structures 42 and extends downward and is spaced apart from the bit lines 25. The insulating pattern 63 may be formed of an insulating material such as silicon nitride. The pad portions 49L may correspond to the conductive region CNT described in FIG. 1, and the insulating pattern 63 may correspond to the insulating pattern INS described in FIG. 1.

The lower structure LS may include an etch stop layer 67 covering the contact structures 42 and the insulating patterns 63. The etch stop layer 67 may be substantially the same as the etch stop layer ESL in FIG. 1. The etch stop layer 67 may be formed of or may include an insulating material. For example, the etch stop layer 67 may include at least one of a SiBN material and a SiCN material.

The upper structure US may further include a memory element such as a capacitor CAP and at least one support layer 72 having an opening.

The capacitor CAP may be or may correspond to a capacitor of a memory cell storing information in a DRAM device. The capacitor CAP may also be referred to as an information storage structure.

The capacitor (CAP) may include first electrodes 80, a second electrode 90 on the first electrodes 80, and a dielectric layer 85 between the first electrodes 80 and the second electrode 90.

Each of the first electrodes 80 may be substantially the same as one of the first electrode (LE in FIGS. 1 and 2) in FIGS. 1 and 2, the first electrode in FIG. 3 (LEa in FIG. 3) and the first electrode in FIG. 4 (LEb in FIG. 4). The second electrode 90 may be substantially the same as one of the second electrode in FIG. 1 (UEa in FIG. 1), the second electrode (UEa in FIG. 2) in FIG. 2, and the second electrode in FIGS. 3 and 4 (UE in FIGS. 3 and 4). For example, the second electrode 90 may include a first upper electrode layer 90L corresponding to the first upper electrode layer UE_La described in FIG. 1 and formed of substantially the same material as the first upper electrode layer UE_La, and a second upper electrode layer 90U corresponding to the second upper electrode layer UE_U described in FIG. 1 and formed of substantially the same material as the second upper electrode layer UE_U.

At least one of the first and second electrodes 80 and 90 may include the first material region M1 and the second material region M2 as illustrated in FIG. 6.

At least one of the first and second electrodes 80 and 90 may include the first material region M1′ and the second material region M2′ as illustrated in FIG. 7.

The dielectric layer 85 may include high-k dielectric, silicon oxide, silicon nitride, silicon oxynitride, or combinations thereof. The dielectric layer 85 may be substantially the same as the dielectric layer DIE described in FIGS. 1 to 5.

The first electrodes 80 may contact and be electrically connected to the pad portions 49L, pass through the etch stop layer 67, and extend upwardly.

Each of the first electrodes 80 may have a columnar shape, but example embodiments are not limited thereto. For example, each of the first electrodes 80 may have a cylindrical or prismatic shape.

The at least one support layer 72 may be substantially the same as the at least one support layer SP described in FIG. 1. The at least one support layer 72 may include a lower support layer 72a and an upper support layer 72b, disposed on different levels. The lower support layer 72a and the upper support layer 72b contact upper regions of the first electrodes 80 and may prevent or reduce the likelihood of the first electrodes 80 from collapsing, and the lower support layer 72a may contact the first electrodes 80 at a level lower than the upper support layer 72b, and prevent or reduce the likelihood of deformation such as bending of the first electrodes 80. The at least one support layer 72 may include an insulating material such as silicon nitride. In the capacitor CAP, the dielectric layer 85 may be disposed along surfaces of the first electrodes 80 and the at least one support layer 72 contacting the first electrodes 80.

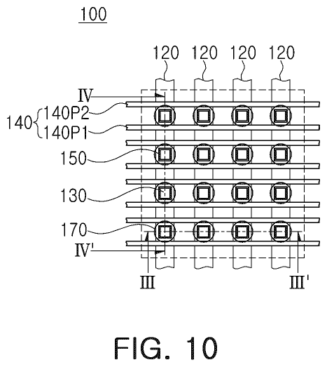

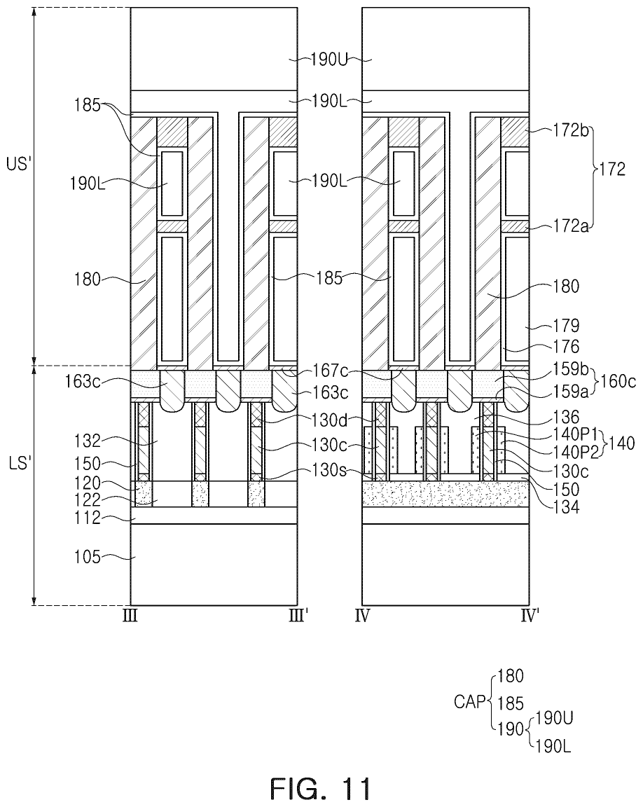

Next, modified examples of the lower structure LS described in FIGS. 8 and 9 will be described with reference to FIGS. 10 and 11. In FIGS. 10 and 11, FIG. 10 is a plan view schematically illustrating a modified example of a semiconductor device according to some example embodiments, and FIG. 11 is a cross-sectional view illustrating a region taken along lines III-III‘ and IV-IV’ of FIG. 10.

Referring to FIGS. 10 and 11, a semiconductor device 100 according to some example embodiments may include a lower structure LS' in which the lower structure LS described in FIGS. 9 and 10 is deformed.

The lower structure LS' may include a substrate 105, a plurality of first conductive lines 120 disposed on the substrate 105, channel regions 130c, lower source/drain regions 130s, upper source/drain regions 130d, cell gate electrodes 140, and cell gate dielectrics 150. The substrate 105 may be a semiconductor substrate.

The channel regions 130c, the lower source/drain regions 130s, the upper source/drain regions 130d, and the cell gate electrodes 140 may constitute or be included in vertical channel transistors. In this case, the vertical channel transistors may also be referred to as cell transistors. The vertical channel transistor may refer to a structure in which the channel length of each of the channel regions 130c extends from the substrate 105 in a vertical direction.

The lower structure LS' may further include a lower insulating layer 112 disposed on the substrate 105. On the lower insulating layer 112, the plurality of first conductive lines 120 may be spaced apart from each other in a second horizontal direction and may extend in a first horizontal direction.

The lower structure LS' may further include a plurality of first lower insulating patterns 122 filling spaces between the plurality of first conductive lines 120, on the lower insulating layer 112. The plurality of first lower insulating patterns 122 may extend in a first horizontal direction, and the upper surfaces of the plurality of first lower insulating patterns 122 may be disposed on the same level as upper surfaces of the plurality of first conductive lines 120. The plurality of first conductive lines 120 may function as column lines or bit lines of the semiconductor device 100.

In an illustrative example, the plurality of first conductive lines 120 may include doped polysilicon, metal, conductive metal nitride, conductive metal silicide, conductive metal oxide, or combinations thereof. For example, the plurality of first conductive lines 120 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or combinations thereof, but is not limited thereto. The plurality of first conductive lines 120 may include a single layer or multiple layers of the aforementioned materials. In an illustrative example, the plurality of first conductive lines 120 may include a two-dimensional semiconductor material, and for example, the two-dimensional semiconductor material may include graphene, carbon nanotubes, or combinations thereof.

The channel regions 130c may be arranged in a matrix form such as a rectangular matrix form, to be spaced apart from each other in the second horizontal direction and the first horizontal direction, on the plurality of first conductive lines 120.

The lower source/drain regions 130s, the channel regions 130c, and the upper source/drain regions 130d may be sequentially stacked.

In some example embodiments, any one channel region 130c, and the lower and upper source/drain regions 130s and 130d disposed below/on the one channel region 130c, may have a first width in the horizontal direction, and a first height in a vertical direction, and the first height may be greater than the first width. For example, the first height may be about 2 to 10 times the first width, but is not limited thereto.

In some illustrative examples, the channel regions 130c may include an oxide semiconductor, and for example, the oxide semiconductor may include InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, or combinations thereof. The channel regions 130c may include a single layer or multiple layers of the oxide semiconductor. In some examples, the channel regions 130c may have a bandgap energy greater than a bandgap energy of silicon. For example, the channel regions 130c may have a bandgap energy of about 1.5 eV to about 5.6 eV. For example, the channel region 130c may have optimal channel performance when it has a bandgap energy of about 2.0 eV to about 4.0 eV. For example, the channel regions 130c may be polycrystalline or amorphous, but are not limited thereto.

In some illustrative examples, the channel regions 130c may include a 2D semiconductor material, and for example, the 2D semiconductor material may include graphene of semiconductor properties, carbon nanotubes of semiconductor properties, or combinations thereof.

In some example embodiments, the channel regions 130c may include a semiconductor material such as silicon or the like.

Hereinafter, although one channel region 130c and one cell gate electrode 140 are mainly described, the channel region 130c and the cell gate electrode 140 may be understood as plural.

The cell gate electrode 140 may extend in the second horizontal direction (X) on both sidewalls of the channel region 130c. The cell gate electrode 140 may include a first sub-gate electrode 140P1 facing the first sidewall of the channel region 130c, and a second sub-gate electrode 140P2 facing a second sidewall opposite to the first sidewall of the channel region 130c. As one channel region 130c is disposed between the first sub-gate electrode 140P1 and the second sub-gate electrode 140P2, the semiconductor device 100 may have a dual-gate transistor structure. However, the technical idea of the present inventive concept is not limited thereto, and the second sub-gate electrode 140P2 is omitted and only the first sub-gate electrode 140P1 facing the first sidewall of the channel region 130c is formed, thereby implementing a single gate transistor structure.

The cell gate electrode 140 may include doped polysilicon, metal, conductive metal nitride, conductive metal silicide, conductive metal oxide, or combinations thereof. For example, the cell gate electrode 140 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, or combinations thereof, but is not limited thereto.

The cell gate dielectric 150 may surround sidewalls of the channel region 130c and may be interposed between the channel region 130c and the cell gate electrode 140. For example, an entire sidewall of the channel region 130c may be surrounded by the cell gate dielectric 150, and a portion of the sidewall of the cell gate electrode 140 may contact the cell gate dielectric 150. In other embodiments, the cell gate dielectric 150 extends in the extension direction of the cell gate electrode 140, for example, in the second horizontal direction X, and among the sidewalls of the channel region 130c, only two sidewalls facing the cell gate electrode 140 may contact the cell gate dielectric 150.

In some example embodiments, the cell gate dielectric 150 may be formed of a silicon oxide layer, a silicon oxynitride layer, a high dielectric film having a higher dielectric constant than the silicon oxide layer, or combinations thereof. The high dielectric film may be formed of metal oxide or metal oxynitride. For example, a high dielectric film usable as the cell gate dielectric 150 may be formed of HfO₂, HfSiO, HfSiON, HOTaO, HfTiO, HfZrO, ZrO₂, Al₂O₃, or combinations thereof, but is not limited thereto.

The lower structure LS' may further include a plurality of second lower insulating patterns 132 disposed on the plurality of first lower insulating patterns 122. The second lower insulating patterns 132 may extend in a first horizontal direction, and a channel region 130c may be disposed between two adjacent second lower insulating patterns 132 among the plurality of second lower insulating patterns 132.

The lower structure LS' may further include a first filling layer 134 and a second filling layer 136 disposed in a space between two adjacent channel regions 130c, between two adjacent second lower insulating patterns 132. The first filling layer 134 is disposed on the bottom portion of a space between two adjacent channel regions 130c, and the second filling layer 136 may be formed to fill the remainder of the space between two adjacent channel regions 130c, on the first filling layer 134. The upper surface of the second filling layer 136 is disposed at the same level as the upper surface of the channel region 130c, and the second filling layer 136 may cover the upper surface of the cell gate electrode 140. Alternatively, the plurality of second lower insulating patterns 132 may be formed of a material layer continuous with the plurality of first lower insulating patterns 122, or the second filling layer 136 may be formed of a material layer continuous with the first filling layer 134.

The lower structure LS' may further include contact structures 160c electrically connected to the upper source/drain regions 130d, on the upper source/drain regions 130d, and insulating patterns 163c between the contact structures 160c.

The contact structures 160c may correspond to the conductive region CNT described in FIG. 1, and the insulating patterns 163c may correspond to the insulating pattern INS described in FIG. 1.

Each of the contact structures 160c may include a barrier layer 159a and a metal layer 159b on the barrier layer 159a. The lower structure LS' may further include an etch stop layer 167c covering the contact structures 160c and the insulating patterns 163c. The etch stop layer 167c may be substantially the same as the etch stop layer ESL in FIG. 1.

The semiconductor device 100 may further include an upper structure US' on the lower structure LS′.

The upper structure US' may further include a capacitor CAP and at least one support layer 172. The capacitor CAP may be a capacitor of a memory cell storing information in a DRAM device. The capacitor CAP may also be referred to as an information storage structure. The capacitor (CAP) may include first electrodes 180, a second electrode 190 on the first electrodes 180, and a dielectric layer 185 between the first electrodes 180 and the second electrode 190.

Each of the first electrodes 180 may be substantially the same as one of the first electrode (LE in FIGS. 1 and 2) in FIGS. 1 and 2, the first electrode in FIG. 3 (LEa in FIG. 3), and the first electrode in FIG. 4 (LEb in FIG. 4). The second electrode 190 may be substantially the same as one of the second electrode in FIG. 1 (UEa in FIG. 1), the second electrode (UEa in FIG. 2) in FIG. 2, and the second electrode in FIGS. 3 and 4 (UE in FIGS. 3 and 4). For example, the second electrode 190 may include a first upper electrode layer 190L corresponding to the first upper electrode layer UE_La described in FIG. 1 and formed of substantially the same material as the first upper electrode layer UE_La, and a second upper electrode layer 190U corresponding to the second upper electrode layer UE_U described in FIG. 1 and formed of substantially the same material as the second upper electrode layer UE_U.

At least one of the first and second electrodes 180 and 190 may include the first material region M1 and the second material region M2 as illustrated in FIG. 6.

At least one of the first and second electrodes 180 and 190 may include the first material region M1′ and the second material region M2′ as illustrated in FIG. 7. The dielectric layer 185 may be substantially the same as the dielectric layer DIE described in FIGS. 1 to 5.

The first electrodes 180 may contact and be electrically connected to the contact structures 160c while penetrating through the etch stop layer 167c, may pass through the etch stop layer 167c and extend upwardly. Each of the first electrodes 180 may have a columnar shape, but embodiments are not limited thereto. For example, each of the first electrodes 180 may have a cylindrical shape.

The at least one support layer 172 may be substantially the same as the at least one support layer SP described in FIG. 1. The at least one support layer 172 may include a lower support layer 172a and an upper support layer 172b disposed on different levels. The lower support layer 172a and the upper support layer 172b contact upper regions of the first electrodes 180 to prevent or reduce the likelihood of the first electrodes 180 from collapsing, and the lower support layer 172a may contact the first electrodes 180 at a level lower than the upper support layer 172b and prevent or reduce the likelihood of deformation such as bending of the first electrodes 180. The at least one support layer 172 may include an insulating material such as silicon nitride. In the capacitor CAP, the dielectric layer 185 may be disposed along surfaces of the first electrodes 180 and the at least one support layer 172 contacting the first electrodes 180.

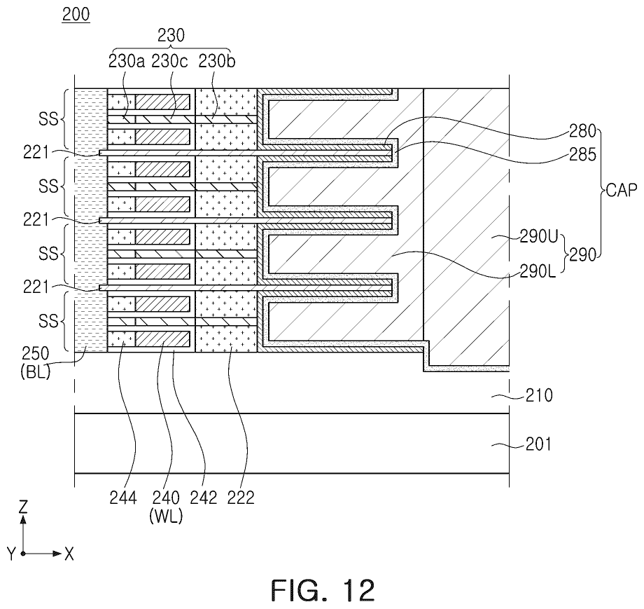

Next, a modified example of a semiconductor device according to some example embodiments will be described with reference to FIG. 12. FIG. 12 is a cross-sectional view illustrating a modified example of a semiconductor device according to some example embodiments.

Referring to FIG. 12, a semiconductor device 200 according to some example embodiments may include a substrate 201, a lower structure 210, a plurality of structures SS, a plurality of first insulating layers 221, and a second conductive pattern 250.

The lower structure 210 may be disposed on the substrate 201. The lower structure 210 may include a device region on the substrate 201 and an insulating region covering the device region. The insulating region may be formed of insulating layers including an insulating material, for example, at least one of silicon oxide, silicon nitride, silicon oxynitride, and silicon oxycarbide.

The second conductive pattern 250 may be disposed on the lower structure 210 and may extend in a Z direction perpendicular to the upper surface of the substrate 201. The second conductive pattern 250 may be a bit line BL.

The plurality of structures SS and the plurality of first insulating layers 221 may be alternately stacked on the lower structure 210. The plurality of structures SS and the plurality of first insulating layers 221 that are alternately stacked may constitute a stack structure SS 221.

Each of the plurality of structures SS may include an active layer 230 extending in the X direction, a first conductive pattern 240 crossing the active layer 230 and extending in a Y direction perpendicular to the X direction, a gate dielectric layer 242 between the active layer 230 and the first conductive pattern 240, a gate capping layer 244 between the first conductive pattern 240 and the second conductive pattern 250, and a second insulating layer 222 covering upper and lower surfaces of the active layer 230. The gate dielectric layer 242 may extend between the first conductive pattern 240 and the second insulating layer 222 from a portion interposed between the active layer 230 and the first conductive pattern 240. The first conductive pattern 240 may be a gate electrode or a word line WL.

The active layers 230 of the plurality of structures SS may be spaced apart from each other in the Z direction and stacked. The active layers 230 may respectively extend horizontally in the X direction. Each of the active layers 230 may have a line shape, a bar shape, or a column shape extending in the X direction while intersecting the first conductive pattern 240.

Each of the active layers 230 may include a first impurity region 230a, a second impurity region 230b, and a channel region 230c. The first impurity region 230a may be a first source/drain region, and the second impurity region 230b may be a second source/drain region.

In each of the active layers 230, the channel region 230c may be disposed between the first impurity region 230a and the second impurity region 230b. The channel region 230c may vertically overlap the first conductive pattern 240. The first impurity regions 230a of the active layers 230 may be electrically connected to the second conductive pattern 250.

The first impurity region 230a, the second impurity region 230b, the channel region 230c, the first conductive pattern 240, and the gate dielectric layer 242 may constitute a cell transistor. Accordingly, the plurality of structures SS may respectively include a cell transistor.

Each of the first insulating layer 221 and the second insulating layer 222 may include an insulating material, for example, at least one of silicon oxide, silicon nitride, silicon oxynitride, and silicon oxycarbide. The thickness of the second insulating layer 222 may be greater than the thickness of the first insulating layer 221.

The active layers 230 may include a semiconductor material, for example, silicon, germanium, or silicon-germanium.

In some other examples, the active layers 230 may include an oxide semiconductor, for example, at least one of hafnium-silicon oxide (HSO), hafnium-zinc oxide (HZO), indium-zinc oxide (IZO), indium-gallium oxide. (IGO), indium-tin oxide (ITO), indium-gallium-zinc oxide (IGZO), and indium-tin-zinc oxide (ITZO).

In some other examples, the active layers 230 may include a two-dimensional material (2D material) in which atoms form a predetermined crystalline structure and may form a channel of a transistor. The 2D material layer may include at least one of a transition metal dichalcogenide material layer (TMD material layer), a black phosphorous material layer, and a hexagonal boron-nitride material layer (hBN material layer). For example, the two-dimensional material layer may include at least one of BiOSe, Crl, WSe₂, MoS₂, TaS, WS, SnSe, ReS, j-SnTe, MnO, AsS, P(black), InSe, h-BN, GaSe, GaN, SrTiO, MXene, and Janus 2D materials, which are capable of forming a two-dimensional material.

The first conductive patterns 240 may respectively extend horizontally in the Y direction. The first conductive patterns 240 are stacked in plurality and spaced apart from each other in the Z direction, and may be arranged in plurality in the X direction.

In each of the plurality of structures SS, the first conductive pattern 240 may be disposed between the channel region 230c of the active layer 230 and the first insulating layer 221. The first conductive pattern 240 may be disposed on upper and lower surfaces of the active layer 230. The first conductive pattern 240 may have a line shape, a bar shape, or a column shape extending in the Y direction while intersecting the second conductive pattern 250.

The first conductive pattern 240 may include a conductive material, and the conductive material may include at least one of a doped semiconductor material, a conductive metal nitride, a metal, and a metal-semiconductor compound.

The semiconductor device 200 may further include a capacitor CAP. The capacitor CAP may include first electrodes 280 electrically connected to the second impurity regions 230b of the active layers 230, a second electrode 290 on the first electrodes 280, and a dielectric layer 285 between the first electrodes 280 and the second electrode 290.

The first electrodes 280 may be spaced apart from each other in the Z direction and stacked. The plurality of first insulating layers 221 may extend between the first electrodes 280 from a portion disposed between the plurality of structures SS. Accordingly, the first electrodes 280 may be spaced apart from each other in the Z direction by the plurality of first insulating layers 221. The first insulating layers 221 may extend into the second conductive pattern 250 from a portion disposed between the plurality of structures SS.

Each of the first electrodes 280 may have a cylindrical shape, but is not limited thereto, and may have a pillar shape or a prismatic shape in various example embodiments.

Each of the first electrodes 280 may be substantially the same as one of the first electrode in FIGS. 1 and 2 (LE in FIGS. 1 and 2), the first electrode in FIG. 3 (LEa in FIG. 3) and the first electrode in FIG. 4 (LEb in FIG. 4). The second electrode 290 may be substantially the same as one of the second electrode in FIG. 1 (UEa in FIG. 1), the second electrode in FIG. 2 (UEa in FIG. 2), and the second electrode in FIGS. 3 and 4 (UE of FIGS. 3 and 4). For example, the second electrode 290 may include a first upper electrode layer 290L corresponding to the first upper electrode layer UE_La described in FIG. 1 and formed of substantially the same material as the first upper electrode layer UE_La, and a second upper electrode layer 290U corresponding to the second upper electrode layer UE_U described in FIG. 1 and formed of substantially the same material as the second upper electrode layer UE_U.

At least one of the first and second electrodes 280 and 290 may include the first material region M1 and the second material region M2 as illustrated in FIG. 6.

At least one of the first and second electrodes 280 and 290 may include the first material region M1′ and the second material region M2′ as illustrated in FIG. 7. The dielectric layer 185 may be substantially the same as the dielectric layer DIE described in FIGS. 1 to 5.

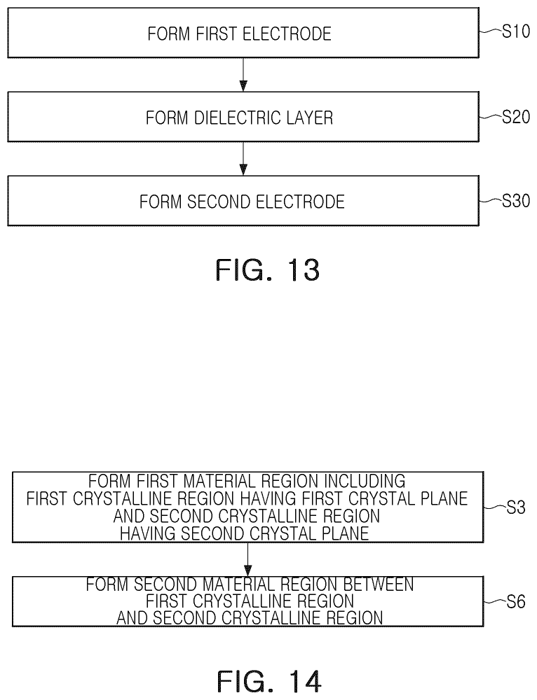

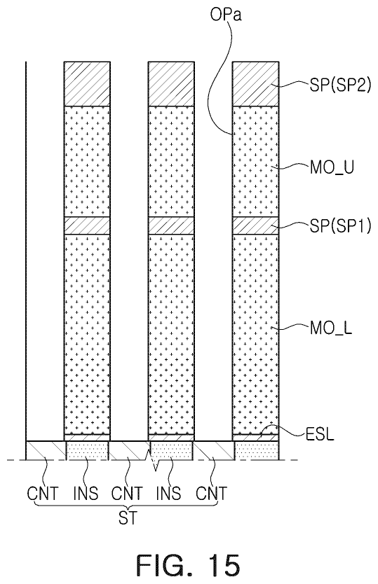

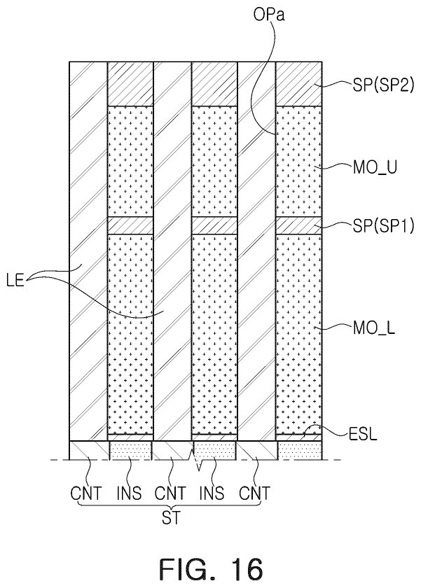

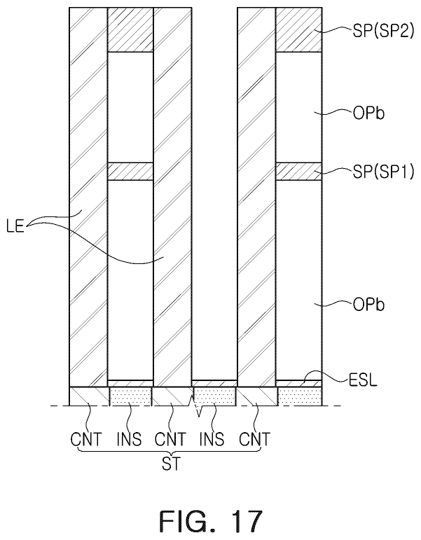

Next, with reference to FIGS. 13 to 17, an illustrative example of a method of forming a semiconductor device according to some example embodiments will be described. FIGS. 13 and 14 are process flow charts illustrating an illustrative example of a method of forming a semiconductor device according to some example embodiments. FIG. 13 is a process flow diagram schematically illustrating a method of forming a capacitor in a semiconductor device according to some example embodiments, and FIG. 14 is a schematic process flow chart illustrating a method of forming at least one of first and second electrodes of a capacitor in a semiconductor device according to some example embodiments. FIGS. 15, 16, and 17 are cross-sectional views schematically illustrating a method of forming a semiconductor device according to some example embodiments.

Referring to FIG. 15, a structure ST including conductive regions CNT and insulating patterns INS may be formed. The structure ST may be the structure ST described with reference to FIGS. 1 and 2, but the example embodiment is not limited thereto. For example, the structure ST may be the lower structure (LS in FIG. 9 or LS' in FIG. 11) described with reference to FIGS. 8 to 11.

A mold structure may be formed on the structure ST. The mold structure may include an etch stop layer (ESL), a lower mold layer (MO_L), a lower support layer (SP1), an upper mold layer (MO_U), and an upper support layer (SP2) sequentially stacked. The lower mold layer MO_L and the upper mold layer MO_U may be formed of the same material, for example, silicon oxide.

An etching process is performed to form first openings OPa that pass through the upper support layer SP2, the upper mold layer MO_U, the lower support layer SP1, the lower mold layer MO_L, and the etch stop layer ESL and expose the conductive regions CNT.

Referring to FIGS. 13, 14, and 16, first electrodes LE may be formed (S10). The first electrodes LE may be formed in the first openings OPa. The first electrodes LE may be formed as one of the first electrode (LE in FIGS. 1 and 2) in FIGS. 1 and 2, the first electrode (LEa in FIG. 3) in FIG. 3, and the first electrode in FIG. 4 (LEb in FIG. 4).

Forming the first electrodes LE may include forming a conductive material covering the upper support layer SP2 while filling the first openings OPa, and planarizing the conductive material.

When the first electrodes LE are formed as the first electrodes (LEa in FIG. 3) in FIG. 3, forming the first electrodes LE may include forming a first material layer (LE_1 in FIG. 3) conformally covering the inner walls of the first openings OPa and covering the upper surface of the upper support layer SP2, forming a second material layer (LE_2 in FIG. 3) filling the first openings OPa on the first material layer LE_1, and planarizing the first and second material layers LE_1 and LE_2.

Forming the first material layer LE_1 may include forming a first material region (M1b in FIG. 3) including a first crystalline region (CP1b in FIG. 3) having a first crystal plane and a second crystalline region (CP2b in FIG. 3) having a second crystal plane (S3), and forming a second material region (M2b in FIG. 3) between the first crystalline region (CP1b in FIG. 3) and the second crystalline region (CP2b in FIG. 3) (S6). The first crystalline region (CP1b in FIG. 3) may have a (111) crystal plane, and the second crystalline region (CP2b in FIG. 3) may have a (200) crystal plane.

The second material region (M2b in FIG. 3) may be the second material region M2′ inserted or doped between the first crystalline region CP1′ having a first columnar shape and the second crystalline region CP2′ having a second columnar shape, and suppressing the preferential growth of the first crystalline region CP1′ in the (111) direction and allowing the second crystalline region CP2′ to be formed more predominately than the first crystalline region CP1′.

When the first electrodes LE are formed as the first electrode (LEa in FIG. 3) in FIG. 3, forming the first material layer LE_1 may include feeding the first precursor, repeatedly performing the first unit process of feeding the reactant once or n times, feeding the first precursor, feeding the second precursor, and repeatedly performing the second unit process of feeding the reactant once to m times.

In this case, n may be 2 or a natural number greater than 2, and m may be 2 or a natural number greater than 2.

In this case, the second precursor may be a precursor having a smaller size than the first precursor.

In this case, n and m may be determined according to the thickness of the first material layer LE_1 and the amount of the material formed by the second precursor in the first material layer LE_1. For example, the thickness of the first material layer UE_L1 may be in the range of about 10 Å to about 40 Å, and in the first material layer LE_1, the amount of the material formed by the second precursor may be about 20 at % or less.

As described in FIG. 3, when forming the first material layer (LE_1 in FIG. 3) that includes the first material region (M1b in FIG. 3) including the first crystalline region (CP1b in FIG. 3) and the second crystalline region (CP2b in FIG. 3) and the second material region (M2b in FIG. 3) between the first crystalline region CP1b and the second crystalline region CP2b, a case in which the material of the first material region (M1b in FIG. 3) is TiN and the material of the second material region (M2b in FIG. 3) is Al will be described with an example.

In some examples, forming the first material layer LE_1 may include feeding the Ti precursor, forming a TiN material region by repeating a first process of feeding an N reactant once or n times, feeding the Ti precursor, feeding the Al precursor, and repeating the second operation of feeding the N reactant once or m times. Forming the first material layer LE_1 may include repeatedly performing the first process and the second process. After forming the first material layer (LE_1 in FIG. 3), the first process may be repeated to form the second material layer (LE_2 in FIG. 3).

In some other examples, forming the first material layer (LE_1 in FIG. 3) may include feeding the Ti precursor, forming a TiN material region by repeating a first process of feeding an N reactant once or n times, and repeating the second process of feeding the Al precursor once or m times. Forming the first material layer (LE_1 in FIG. 3) may include repeatedly performing the first process and the second process.

The Ti precursor may be Tetra-chloro Titanium (TiCl₄) gas, but example embodiments are not limited thereto. The N reactant may be NH₃ gas, but example embodiments are not limited thereto. The Al precursor may be trimethylaluminum[TMA, Al(CH₃)₃], but example embodiments are not limited thereto. For example, as a Ti precursor, etrikis-Dimethylamino Titanium (TDMAT, Ti[N(CH₃)₂]₄) may be used, and as an Al precursor, tris(dimethylamido) aluminum (TDMAA, Al[(CH₃)₂N]₄) or aluminum chloride (AlCl₃) may also be used.

In some other examples, instead of the Ti precursor, a Hf precursor, a Cr precursor, a Nb precursor, or a Zr precursor may be used.

In some other examples, a Si precursor or B precursor may be used instead of the Al precursor.

Referring to FIGS. 13, 14, and 17, openings are formed to penetrate the upper support layer SP2, the upper mold layer MO_U, and the lower support layer SP1, and a second opening OPb may be formed by removing the upper mold layer MO_U and the lower mold layer MO_L exposed by the openings.

The upper support layer SP2 and the lower support layer SP1 may constitute a support layer SP. The first electrodes LE may be supported by the support layer SP.

Referring back to FIG. 1, a dielectric layer (DIE) may be formed (S20). The dielectric layer DIE may be conformally formed along surfaces of the first electrodes LE and the support layer SP on the structure SS. A second electrode UEa may be formed (S30). The second electrode UEa may fill the second opening OPb and cover the dielectric layer DIE and the first electrodes LE.

Forming the second electrode UEa may include forming a first upper electrode layer UE_La, and forming a second upper electrode layer UE_U on the first upper electrode layer UE_La. The second electrode UEa may be formed of the second electrode of FIG. 2 (UEa of FIG. 2) and the second electrode of FIG. 5 (UEa of FIG. 5).

As illustrated in FIG. 1, the first upper electrode layer UE_La may include the first material layer UE_L1 and the second material layer UE_L2 on the first material layer UE_L1.

Forming the first material layer (UE_L1 in FIG. 1) of the first upper electrode layer (UE_La in FIG. 1) may include forming a first material region (M1a in FIG. 1) including a first crystalline region (CP1a in FIG. 1) having a first crystal plane and a second crystalline region (CP2a in FIG. 1) having a second crystal plane (S3), and forming a second material region (M2a in FIG. 1) between the first crystalline region (CP1a in FIG. 1) and the second crystalline region (CP2a in FIG. 1) (S6).

Forming the first material layer (UE_L1 in FIG. 1) of the first upper electrode layer (UE_La in FIG. 1) may be substantially the same as forming the first material layer LE_1 of the first electrode LE described above with reference to FIGS. 13, 14, and 16. Therefore, a detailed description of forming the first material layer (UE_L1 in FIG. 1) of the first upper electrode layer (UE_La in FIG. 1) will be omitted.

As set forth above, according to various example embodiments, a semiconductor device including a capacitor including a first electrode, a second electrode, and a dielectric layer between the first electrode and the second electrode may be provided. At least one of the first electrode and the second electrode may include a first material region including a first crystalline region and a second crystalline region different from the first crystalline region, and a second material region between the first crystalline region and the second crystalline region. The second crystalline region may have a (200) crystal plane, and the first crystalline region may have a (111) crystal plane. A work function of the second crystalline region may be greater than a work function of the first crystalline region.

In some example embodiments, the second material region may serve or help to form the second crystalline region more predominantly than the first crystalline region in the first material region. Therefore, due to the second material region, the amount (the volume of) of the second crystalline region may be equal to or greater than the amount of (the volume of) the first crystalline region, in the first material region.

As such, since at least one of the first electrode and the second electrode includes the first material region and the second material region, leakage current of the capacitor CAP may be reduce or significantly reduced, and/or capacitance of the capacitor may be increased. Accordingly, a semiconductor device including a capacitor with improved performance may be provided.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Moreover, when the words “generally” and “substantially” are used in connection with material composition, it is intended that exactitude of the material is not required but that latitude for the material is within the scope of the disclosure.

Further, regardless of whether numerical values or shapes are modified as “about” or “substantially,” it will be understood that these values and shapes should be construed as including a manufacturing or operational tolerance (e.g., ±10%) around the stated numerical values or shapes. Thus, while the term “same,” “identical,” or “equal” is used in description of example embodiments, it should be understood that some imprecisions may exist. Thus, when one element or one numerical value is referred to as being the same as another element or equal to another numerical value, it should be understood that an element or a numerical value is the same as another element or another numerical value within a desired manufacturing or operational tolerance range (e.g., ±10%).

While various example embodiments have been illustrated and described above, it will be apparent to those skilled in the art that modifications and variations could be made without departing from the scope of inventive concepts as defined by the appended claims. Additionally, example embodiments are not necessarily mutually exclusive with one another. For example, some example embodiments may include one or more features described with reference to one or more figures, and may also include one or more other features described with reference to one or more other figures.

What is claimed is:

1. A semiconductor device comprising:
a structure including a conductive region; and
a capacitor electrically connected to the conductive region of the structure,
wherein the capacitor includes a first electrode electrically connected to the conductive region, a second electrode on the first electrode, and a dielectric layer between the first electrode and the second electrode,
wherein at least one of the first electrode and the second electrode includes,
a first material layer including a first material region including a first crystalline region and a second crystalline region different from the first crystalline region, and a second material region between the first crystalline region and the second crystalline region, and
a second material layer on the first material layer,
wherein at least a portion of the first material layer is between the second material layer and the dielectric layer, and
a material of the first material region is different from a material of the second material region.

2. The semiconductor device of claim 1, wherein the second material layer includes a same material as the material of the first material region.

3. The semiconductor device of claim 2, wherein the material of the first material region and the material of the second material layer are metal nitrides.

4. The semiconductor device of claim 1, wherein
the material of the first material region and a material of the second material layer include at least one of TiN, CrN, NbN, HfN, or ZrN, and
the material of the second material region includes at least one of Al, Si, or B.

5. The semiconductor device of claim 1, wherein in the first material layer, materials in the second material region are 20 at % or less.

6. The semiconductor device of claim 1, wherein a thickness of the first material layer is in a range of 10 Å to 40 Å.

7. The semiconductor device of claim 1, wherein
the second electrode includes the first material layer and the second material layer, and
the first electrode does not include the first material layer.

8. The semiconductor device of claim 1, wherein
the second electrode further includes a third material layer on the second material layer, and
wherein the third material layer includes a material different from materials of the first and second material layers.

9. The semiconductor device of claim 1, wherein
the first electrode includes the first material layer and the second material layer, and
in the first electrode, the second material layer has a columnar shape, and the first material layer covers a side surface of and a bottom surface of the second material layer.

10. The semiconductor device of claim 9, wherein the second electrode does not include the first material layer.

11. The semiconductor device of claim 1, wherein each of the first electrode and the second electrode includes the first material layer and the second material layer.

12. A semiconductor device comprising:
a structure including conductive regions; and
a capacitor electrically connected to the structure,
wherein the capacitor includes first electrodes electrically connected to the conductive regions, a second electrode on the first electrodes, and a dielectric layer between the first electrodes and the second electrode,
wherein at least one of the first electrodes and the second electrode includes,
a first material region including a first crystalline region having a (111) crystal plane and a second crystalline region having a (200) crystal plane, and
a second material region between the first crystalline region and the second crystalline region,
wherein a material of the first material region is different from a material of the second material region, and
in the first material region, a volume of the second crystalline region is greater than or equal to a volume of the first crystalline region.

13. The semiconductor device of claim 12, wherein a thickness of a material layer including the first material region and the second material region is in a range of 10 Å to 40 Å.

14. The semiconductor device of claim 12, wherein in a material layer including the first material region and the second material region, the materials of the second material region are about 20 at % or less.

15. The semiconductor device of claim 12, wherein
one or more materials of the first material region includes at least one of TiN, CrN, NbN, HfN, or ZrN, and
one or more materials of the second material region includes at least one of Al, Si, or B.

16. The semiconductor device of claim 12, wherein
the first material region is in contact with the dielectric layer, and
the second material region is spaced apart from the dielectric layer.

17. The semiconductor device of claim 12, wherein
the first material region is in contact with the dielectric layer, and
the second material region is in contact with the dielectric layer.

18. A semiconductor device comprising:
a structure including conductive regions; and
a memory element electrically connected to the conductive regions of the structure,
wherein the memory element includes first electrodes electrically connected to the conductive regions, a second electrode on the first electrodes, and a dielectric layer between the first electrodes and the second electrode,
wherein at least one of the first electrodes and the second electrode includes,
a first material region including a first crystalline region of a first columnar shape and a second crystalline region of a second columnar shape, different from the first columnar shape, and
a second material region between the first crystalline region and the second crystalline region,
wherein a material of the first material region is different from a material of the second material region,
in the first material region, a volume of the second crystalline region is equal to or greater than a volume of the first crystalline region, and
a work function of the second crystalline region is greater than a work function of the first crystalline region.

19. The semiconductor device of claim 18, wherein
the first crystalline region has a (111) crystal plane, and
the second crystalline region has a (200) crystal plane.

20. The semiconductor device of claim 18, wherein
one or more materials of the first material region includes at least one of TiN, CrN, NbN, HfN, or ZrN, and
one or more materials of the second material region includes at least one of Al, Si, or B.
